(19) United States
(12) Patent Application Publication
(10) Pub. No.: US 2025/0275370 A1
(43) Pub. Date: Aug. 28, 2025

(54) ORGANIC LIGHT EMITTING DISPLAY DEVICE

(71) Applicant: LG Display Co., Ltd., Seoul (KR)

(72) Inventors: Yosup SIM, Paju-si (KR); Yongmin KIM, Paju-si (KR); Seungpyo HONG, Paju-si (KR)

(21) Appl. No.: 18/908,406

(22) Filed: Oct. 7, 2024

(30) Foreign Application Priority Data
Feb. 28, 2024 (KR) 10-2024-0028480

(51) Int. Cl. H10K 59/122; H10K 59/123; H10K 59/124

(52) U.S. Cl. CPC H10K 59/122; H10K 59/123; H10K 59/124

(57) ABSTRACT

The present disclosure provides a display device. The device includes a pixel area and a transmissive area. The device includes an overcoat layer in the pixel area and a first insulating pattern on the overcoat layer. The first insulating pattern includes a first opening exposing a portion of the overcoat layer and a first inclined surface exposed by the first opening. The device includes an anode electrode on the portion of the overcoat layer exposed through the first opening and the first inclined surface of the first insulating pattern. The device includes an auxiliary electrode in the transmissive area and a second insulating pattern on the auxiliary electrode. The second insulating pattern includes a second opening exposing a portion of the auxiliary electrode and a second inclined surface exposed by the second opening. The device may include a connection electrode, an emission layer, and a cathode electrode.

### CROSS-REFERENCE TO RELATED APPLICATION

This application claims the priority benefit of Republic of Korea Patent Application No. 10-2024-0028480, filed on Feb. 28, 2024 in the Korean Intellectual Property Office, which is incorporated herein by reference for all purposes as if fully set forth herein.

### BACKGROUND

### Technical Field

The present disclosure relates to electronic devices with displays, and more specifically, to an organic light emitting display device.

### Description of the Related Art

In today's information-oriented society, display devices for displaying images have become increasingly important. To meet various needs for display devices, various types of displays, such as liquid crystal displays (LCD), organic light emitting displays (OLED), micro light emitting displays (micro LED), mini light emitting displays (mini LED), quantum dot light emitting displays (QLED), and the like have been developed and widely used.

Among these displays, organic light emitting displays (OLED), which use self-emissive light emitting diodes, can have a wide viewing angle, a high contrast ratio, a fast response speed, and the like, and have the advantages of being implemented with light weight and thin package and consuming much less power as a separate light source such as a back-light unit is not required, compared with liquid crystal displays (LCD). Further, organic light emitting displays (OLED) can have the advantages of being driven at low voltage, and being manufactured at low costs.

### BRIEF SUMMARY

An organic light emitting element such as an organic light emitting diode and the like may include an anode electrode and a cathode electrode, which face each other, and an emission layer, which is located between the anode electrode and the cathode electrode and is capable of emitting light based on a driving current flowing therebetween. The anode electrode may be disposed in each subpixel, and the cathode electrode may be disposed commonly in two or more of a plurality of subpixels.

Unlike the anode electrode, which may be disposed in each subpixel, as the cathode electrode is configured to correspond to two or more of the plurality of subpixels, the cathode electrode may have a higher resistance compared with the anode electrode.

For example, when an organic light emitting display device is implemented with a top-emission structure, a transparent or translucent electrode may be used as the cathode electrode to direct light emitted from the emission layer upward. In this example, when the cathode electrode having transparent or translucent properties is used, the cathode electrode may be required to have a small thickness to improve transmittance, thereby, a reduction in the thickness of the cathode electrode leading the resistance of the cathode electrode to increase. In this case, a voltage applied to the cathode electrode may drop due to the high resistance of the cathode electrode, and thereby, a voltage difference between the anode and cathode electrodes of the organic light emitting element may be reduced. In the case of an organic light emitting display device with a large area, as a distance from a voltage supply pad located in an edge portion of the organic light emitting display device increases, that is, the closer the anode and cathode electrodes is to the center of the organic light emitting display device, the greater a voltage difference between the anode and cathode electrodes is reduced. Thereby, the organic light emitting display device can suffer from luminance imbalance.

In addition, to present luminance greater than or equal to a critical level despite the voltage drop due to the high resistance of the cathode electrode, a high voltage is needed to be supplied, and thereby, the power consumption of the organic light emitting display device can be increased.

Various methods have been developed to reduce such voltage drop in organic light emitting display devices with the top-emission structure,

The inventors of the present disclosure have developed a technique of forming an auxiliary electrode under an emission layer to reduce voltage drop, and forming a cathode contact by irradiating a portion where the auxiliary electrode is formed with laser light from a laser, and electrically connecting the auxiliary electrode and a cathode electrode. In a structure in which the emission layer is formed on the auxiliary electrode, and the cathode electrode is formed on the emission layer, when the auxiliary electrode is irradiated by laser beams with high intensity, a portion of the emission layer irradiated by laser beams may be melted due to the instantaneous heat energy from the laser beams, and thereby, the auxiliary electrode and the cathode electrode can be electrically connected.

In an example where the organic light emitting display device is implemented as a transparent organic light emitting display device, a display area of the transparent organic light emitting display device may include a pixel area where subpixels are disposed and a transmissive area allowing external light to be transmitted, and when a cathode contact is disposed in the pixel area, the anode electrode and the cathode electrode may be electrically connected to each other. Thereby, some pixels of the organic light emitting device may not emit light, and image quality of the organic light emitting device may be degraded. In addition, as laser beams carry strong energy, considering that energy from the laser beams may extend to about 1.5 times an area irradiated by the laser beams, a cathode contact may be located in the transmissive area, rather than the pixel area in which components vulnerable to the laser irradiation, such as thin film transistors, capacitors, and the like, are disposed.

To form a cathode contact, it is necessary for a portion of an emission layer irradiated by laser beams to be melted and removed by the instantaneous heat energy from the laser beams, but, when the emission layer is not properly removed, the cathode contact may not be formed. That is, cathode contact failure may occur. In order to increase the probability of successfully forming cathode contacts, an area of each cathode contact or the number of cathode contacts may be increased, but in this case, the transparency of the transmissive area may be reduced.

To address these issues, one or more aspects of the present disclosure may provide an organic light emitting display device capable of increasing the probability of successfully forming cathode contacts.

One or more aspects of the present disclosure may provide an organic light emitting display device capable of improving transparency of a transmissive area by reducing the number of cathode contacts and reducing an area occupied by each cathode contact.

One or more aspects of the present disclosure may provide an organic light emitting display device capable of reducing the width of the bezel.

In addition to the aspects above described, other aspects, embodiments and examples of the present disclosure and resulted advantages will be described below, and variations thereof will become apparent to those skilled in the art from the following detailed description.

According to one or more example embodiments of the present disclosure, an organic light emitting display device can be provided that includes: a substrate in which a pixel area and a transmissive area are defined; an overcoat layer disposed over the substrate in the pixel area; a first insulating pattern disposed on the overcoat layer, and including a first opening exposing a portion of the overcoat layer and a first inclined surface exposed by the first opening; an anode electrode disposed on the portion of the overcoat layer exposed through the first opening and the first inclined surface of the first insulating pattern; an auxiliary electrode disposed over the substrate in the transmissive area; a second insulating pattern disposed on the auxiliary electrode, and including a second opening exposing a portion of the auxiliary electrode and a second inclined surface exposed by the second opening; a connection electrode including a flat portion disposed on the portion of the auxiliary electrode exposed through the second opening and an inclined portion disposed on the second inclined surface of the second insulating pattern; an emission layer disposed in the pixel area and the transmissive area and covering the anode electrode and the connection electrode; and a cathode electrode disposed on the emission layer, and including a cathode contact passing through the emission layer and contacting the flat portion and the inclined portion of the connection electrode.

According to one or more example embodiments of the present disclosure, an organic light emitting display device can be provided that includes: a first substrate in which a display area and a non-display area surrounding the display area are defined; a second substrate facing the first substrate and overlapping with the first substrate; at least one thin film transistor disposed over the first substrate in the display area; an interlayer insulating layer disposed over the first substrate and covering the at least one thin film transistor; a passivation layer disposed on the interlayer insulating layer; an overcoat layer disposed on the passivation layer in the display area; a first insulating pattern disposed on the overcoat layer, and including a first opening exposing a portion of the overcoat layer and a first inclined surface exposed by the first opening; an anode electrode disposed on the portion of the overcoat layer exposed through the first opening and the first inclined surface of the first insulating pattern; a bank disposed on the first insulating pattern and the anode electrode, and exposing a portion of the anode electrode disposed on the bottom of the first opening; at least one dam disposed on the passivation layer in the non-display area, and surrounding the display area. The at least one dam may include a plurality of layers, and one of the plurality of layers may include the same material as the first insulating pattern.

According to one or more example embodiments of the present disclosure, an organic light emitting display device can be provided that includes: a substrate in which a pixel area and a transmissive area are defined; an anode electrode disposed over the substrate in the pixel area; an auxiliary electrode disposed over the substrate in the transmissive area; an insulating pattern disposed on the auxiliary electrode, and including an opening exposing a portion of the auxiliary electrode and an inclined surface exposed by the opening; a connection electrode including a flat portion disposed on the portion of the auxiliary electrode exposed through the opening and an inclined portion disposed on the inclined surface of the insulating pattern; an emission layer disposed in the pixel area and the transmissive area, and covering the anode electrode and the connection electrode; and a cathode electrode disposed on the emission layer, and including a cathode contact passing through the emission layer and contacting the flat portion and the inclined portion of the connection electrode.

According to one or more aspects of the present disclosure, an organic light emitting display device may be provided that is capable of improving transparency of a transmissive area by reducing the number of cathode contacts and reducing an area occupied by each cathode contact.

According to one or more aspects of the present disclosure, an organic light emitting display device may be provided that is capable of increasing the probability of successfully forming cathode contacts without reducing the transparency of a transmissive area by increasing an area contacted by each cathode contact without reducing an area occupied by each cathode contact.

According to one or more aspects of the present disclosure, an organic light emitting display device may be provided that is capable of increasing the probability of successfully forming cathode contacts by reducing the thickness of an emission layer disposed in an area where each cathode contact is formed, and thereby, causing the emission layer to be easily removed in the process of removing the emission layer using a laser.

According to one or more aspects of the present disclosure, an organic light emitting display device may be provided that is capable of being driven with low power by lowering the resistance of a cathode electrode and reducing voltage drop. According to this configuration, the organic light emitting display device can provide an advantage of reducing power consumption.

According to one or more aspects of the present disclosure, an organic light emitting display device may be provided that is capable of lengthening a path through which moisture penetrates, and improving the reliability of the display device by preventing or reducing the penetration of moisture coming from outside of the organic light emitting display device.

According to one or more aspects of the present disclosure, an organic light emitting display device may be provided that is capable of lengthening a path through which moisture penetrates, and enabling a narrow bezel to be achieved by preventing or reducing the penetration of moisture without increasing the width of the bezel.

Additional examples, aspects, and embodiments of the present disclosure will be set forth in part in the description which follows and in part will become apparent from the description or may be learned by practice of the inventive concepts provided herein. Other features and aspects of the inventive concepts may be realized and attained by the structure particularly pointed out in, or derivable from, the written description, the claims hereof, and the appended drawings. Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims. It is to be understood that both the foregoing general description and the following detailed description of the present disclosure are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates the configuration of an example organic light emitting display device according to aspects of the present disclosure;

FIG. 2 illustrates an example configuration of a display panel included in the organic light emitting display device according to aspects of the present disclosure;

FIG. 3 illustrates an example circuit of a subpixel of the organic light emitting display device according to aspects of the present disclosure;

FIG. 4 is a plan view illustrating an example portion of a display area of the display panel of the organic light emitting display device according to aspects of the present disclosure;

FIG. 5 is a plan view illustrating an anode electrode, an emission layer, a cathode electrode, an auxiliary electrode, a power voltage line, data lines, and a cathode contact in the organic light emitting display device according to aspects of the present disclosure;

FIG. 6 is an example cross-sectional view of the organic light emitting display device according to aspects of the present disclosure;

FIGS. 7A to 7C, 8A to 8B, and 9A to 9B are perspective views illustrating the process of forming a cathode contact in the organic light emitting display device according to aspects of the present disclosure;

FIG. 10 illustrates an example situation where light emitted from an emission layer is reflected by an anode electrode in the organic light emitting display device according to aspects of the present disclosure;

FIG. 11 is a plan view illustrating example light emitting portions and example non-light emitting portions in the organic light emitting display device according to aspects of the present disclosure; and

FIGS. 12 to 14 are example cross-sectional views illustrating an inner dam, an outer dam, and a sealing dam in the organic light emitting display device according to aspects of the present disclosure.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

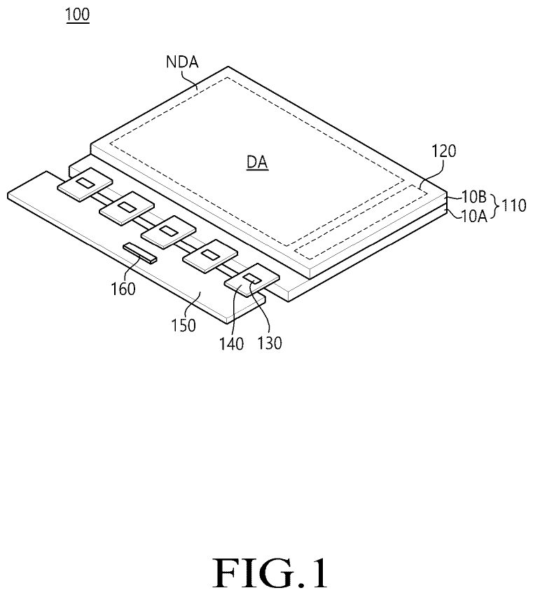

FIG. 1 illustrates the configuration of an example organic light emitting display device according to aspects of the present disclosure.

Referring to FIG. 1, in one or more example embodiments, an organic light emitting display device 100 may include a display panel 110, a gate driver 120, a data driver 130, a flexible film 140, a circuit board 150, a controller 160, and the like.

The display panel 110 may include a first substrate 10A and a second substrate 10B. The first substrate 10A may be a pixel array substrate, and the second substrate 10B may be an encapsulation substrate or a color filter substrate. The first substrate 10A and the second substrate 10B may be prepared in separate processes, and thereafter, bonded to each other.

Gate lines, data lines, and subpixels may be disposed on one surface of the first substrate 10A facing the second substrate 10B. The subpixels may be disposed in areas in which the gate lines and the data lines intersect each other. Each of the subpixels may include at least one thin film transistor, and an organic light emitting element such as an organic light emitting diode, and the like. In each of the subpixels, when a gate signal delivered through a gate line is applied to a scan transistor, a driving transistor can supply a driving current depending on a data voltage delivered through a data line to an organic light emitting element. According to this operation, the organic light emitting element can emit light with a predetermined brightness depending on the supplied driving current.

The display panel 110 may include a display area DA where a plurality of subpixels are disposed, and a non-display area NDA located outside of the display area DA. The non-display area NDA may also be referred to as a bezel area.

The gate driver 120 can supply gate signals to gate lines according to gate control signals supplied by the controller 160. In one or more aspects, one or more gate drivers 120 may be disposed in, and/or electrically connected to, but not limited to, one or more respective portions of the non-display area NDA located outside of one side edge or both opposing side edges of the display area DA of the display panel 110 by a gate-in-panel (GIP) technique. In one or more aspects, the one or more gate drivers 120 may be manufactured in the form of driving chip and mounted on the flexible film 140, or disposed in, and/or electrically connected to, but not limited to, one or more respective portions of the non-display area NDA located outside of one side edge or both opposing side edges of the display area DA of the display panel 110 by a tape-automated-bonding (TAB) technique.

The data driver 130 can receive digital image data and source control signals from the controller 160. The data driver 130 can convert the digital image data into analog data voltages according to the source control signals and supply the resulting data voltages to data lines. In one or more aspects, the data driver 130 may be manufactured in the form of driving chip, and be mounted on the flexible film 140 by a chip-on-film (COF) technique or a chip-on-panel (COP) technique. Pads such as data pads may be disposed in the non-display area NDA of the display panel 110. Lines connecting the pads and one or more data drivers 130 and lines connecting the pads and the lines of the circuit board 150 may be disposed in the flexible film 140. The flexible film 140 may be attached to the pads using an anisotropic conducting film, and thereby, the pads and the lines of the flexible film 140 may be connected.

The circuit board 150 may be attached to the flexible films 140. A plurality of circuits implemented in the form of driving chip may be mounted on the circuit board 150. For example, the controller 160 may be mounted on the circuit board 150. The circuit board 150 may be a printed circuit board or a flexible printed circuit board.

The controller 160 may receive digital image data and timing signals from an external system or device through a cable of the circuit board 150. The controller 160 may generate one or more gate control signals for controlling the operation timing of one or more gate drivers 120 and one or more source control signals for controlling one or more data drivers 130 based on the timing signals. The controller 160 can supply the one or more gate control signals to the one or more gate drivers 120 and the one or more source control signals to the one or more data drivers 130.

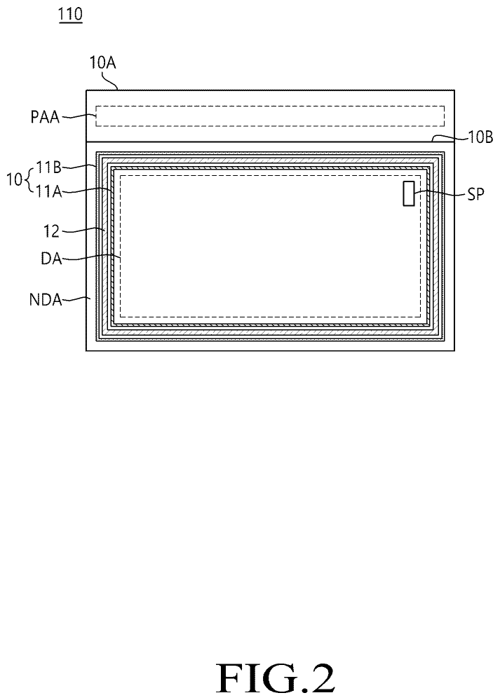

FIG. 2 illustrates an example configuration of the display panel 110 included in the organic light emitting display device according to aspects of the present disclosure.

Referring to FIG. 2, in one or more example embodiments, a display area DA and a non-display area NDA of the display panel 110 may be disposed in an area where a first substrate 10A (e.g., the first substrate 10A of FIG. 1) and a second substrate 10B (e.g., the second substrate 10B of FIG. 1) overlap with each other.

A plurality of subpixels SP may be disposed in the display area DA. The non-display area NDA may be located outside of the display area DA and be configured to surround the display area DA. An inner dam 11A, a sealing dam 12, and an outer dam 11B may be disposed in the non-display area NDA, and thus, be configured to sequentially surround the display area DA from a plan view.

The second substrate 10B may overlap with the first substrate 10A and have a smaller size than the first substrate 10A. However, example embodiments of the present disclosure are not limited to this. For example, the first substrate 10A and the second substrate 10B may have the same size or may be variously determined according to design requirements.

A pad area PAA of the display panel 110 may be disposed in one portion or side of the non-display area NDA. The pad area PAA may be disposed in a portion of the first substrate 10A not overlapping the second substrate 10B, but example embodiments of the present disclosure are not limited thereto. The flexible film 140 described with reference to FIG. 1 may be mounted in the pad area PAA.

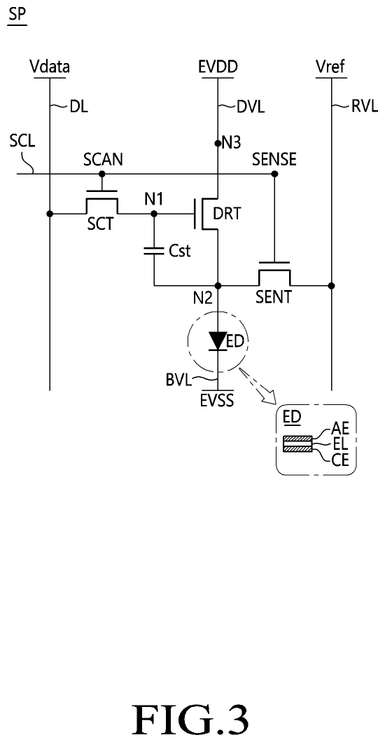

FIG. 3 illustrates an example circuit of a subpixel of the organic light emitting display device 100 according to aspects of the present disclosure.

Referring to FIG. 3, in one or more example embodiments, each subpixel disposed in the display panel 110 may include a light emitting element ED such as an organic light emitting diode and the like, a driving transistor DRT for driving the light emitting element ED, a scan transistor SCT for passing a data voltage Vdata to a first node N1 of the driving transistor DRT, a storage capacitor Cst for maintaining a voltage at a predetermined constant level during one frame, and the like.

The driving transistor DRT may include the first node N1 to which a data voltage is applied, a second node N2 electrically connected to the light emitting element ED, and a third node N3 to which a driving voltage EVDD through a driving voltage line DVL is applied. In the driving transistor DRT, the first node N1 may be a gate node, the second node N2 may be a source node or a drain node, and the third node N3 may be the drain node or the source node. Hereinafter, for convenience of description, the first node N1 of the driving transistor DRT is also referred to as a gate node or a gate electrode, the second node N2 of the driving transistor DRT is also referred to as a source node or a source electrode, and the third node N3 of the driving transistor DRT is also referred to as a drain node or a drain electrode.

The light emitting element ED may include an anode electrode AE, an emission layer EL, and a cathode electrode CE. The anode electrode AE of the light emitting element ED may be electrically connected to the second node N2 of the driving transistor DRT of each subpixel SP. The cathode electrode CE of the light emitting element ED may be electrically connected to a base voltage line BVL to which a base voltage EVSS is applied.

The anode electrode AE may be a pixel electrode disposed in each subpixel SP. The cathode electrode CE may be a common electrode to which the base voltage EVSS, which is a type of common voltage commonly needed to drive the subpixels SP, is applied.

The scan transistor SCT can be turned on and off by a scan signal SCAN, which is a gate signal applied through a scan signal line SCL, and be electrically connected between the first node N1 of the driving transistor DRT and a data line DL.

The storage capacitor Cst may be connected between the first node N1 and the second node N2 of the driving transistor DRT. The storage capacitor Cst may be an external capacitor intentionally designed to be located outside of the driving transistor DRT, and therefore, be different from an internal capacitor such as a parasitic capacitor (e.g., a Cgs, a Cgd) that may be formed between the first node N1 and the second node N2 of the driving transistor DRT.

The subpixel SP may include a light emitting element ED, two transistors (2T: DRT and SCT) and one capacitor (1C: Cst), and in some implementations, may further include one or more transistors, and/or further include one or more capacitors.

For example, as shown in FIG. 3, each subpixel SP may further include a sensing transistor SENT for controlling a connection between the second node N2 of the driving transistor DRT and a reference voltage line RVL. The reference voltage line RVL may be a signal line for supplying a reference voltage Vref to the subpixel SP.

As shown in FIG. 3, in one or more aspects, the gate node of the sensing transistor SENT may be electrically connected to the gate node of the scan transistor SCT. That is, the scan signal line SCL electrically connected to the gate node of the scan transistor SCT may also be electrically connected to the gate node of the sensing transistor SENT.

In one or more aspects, the gate node of the sensing transistor SENT may be electrically connected to a sensing signal line or another scan signal line other than the scan signal line SCL connected to the gate node of the scan transistor SCT.

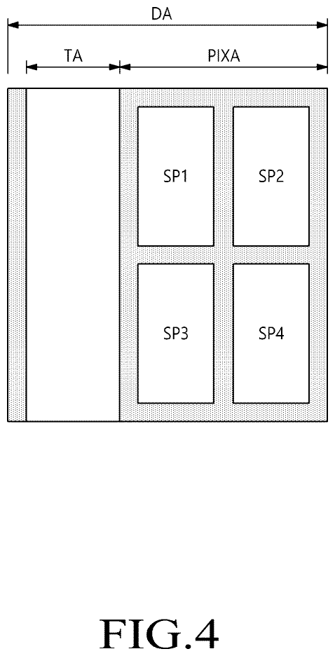

FIG. 4 is a plan view illustrating an example portion of the display area of the display panel of the organic light emitting display device according to aspects of the present disclosure.

Referring to FIG. 4, in one or more example embodiments, the display area DA of the display panel 110 may include a pixel area PIXA and a transmissive area TA. Although FIG. 4 shows one pixel area PIXA and one transmissive area TA, it should be noted that the display area DA may include a plurality of pixel areas PIXA and a plurality of transmissive areas TA.

Two or more subpixels (SP1, SP2, SP3, and SP4) may be disposed in each pixel area PIXA. For example, four subpixels (SP1, SP2, SP3, and SP4) may be disposed in each pixel area PIXA. The four subpixels (SP1, SP2, SP3, and SP4) include a red subpixel SP1 that emits red light, a green subpixel SP2 that emits green light, a blue subpixel SP3 that emits blue light, and a white subpixel SP4 that emits white light.

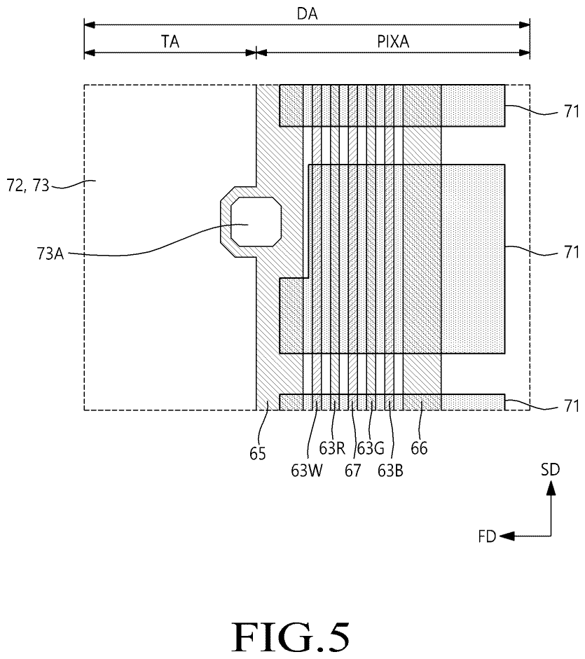

FIG. 5 is a plan view illustrating an anode electrode, an emission layer, a cathode electrode, an auxiliary electrode, a power voltage line, data lines, and a cathode contact in the organic light emitting display device according to aspects of the present disclosure.

Referring to FIG. 5, a plurality of anode electrodes 71 may be disposed in the pixel area PIXA. The anode electrodes 71 may respectively correspond to light emitting areas of subpixels.

An emission layer 72 and a cathode electrode 73 may be configured to correspond to all or at least part of the entire surface of the display area DA. That is, the emission layer 72 and the cathode electrode 73 may be configured to correspond to all or at least part of a plurality of transmissive areas TA and a plurality of pixel areas PIXA included in the display area DA. The emission layer 72 and the cathode electrode 73 may correspond to all of the plurality of subpixels disposed in the display area DA. A light emitting element such as an organic light emitting diode and the like included in each subpixel may include the anode electrode 71, the cathode electrode 73, and the emission layer 72 interposed between the anode electrode 71 and the cathode electrode 73.

Data lines (63W, 63R, 63G, and 63B), an auxiliary electrode 65, a power voltage line 66, and a reference voltage line 67 may be disposed in the pixel area PIXA.

The data lines (63W, 63R, 63G, and 63B) may include a first data line 63W for delivering a data voltage to a white subpixel, a second data line 63R for delivering a data voltage to a red subpixel, a third data line 63G for delivering a data voltage to a green subpixel, and a fourth data line 63B for delivering a blue subpixel.

The auxiliary electrode 65 may be connected to a low voltage line (not shown) and serve to deliver a low power supply voltage to the cathode electrode 73 at multiple locations. The auxiliary electrode 65 may be disposed in parallel with the data lines (63W, 63R, 63G, and 63B) in the pixel area PIXA. In the pixel area PIXA, the data lines (63W, 63R, 63G, and 63B) and the auxiliary electrode 65 may extend in a second direction SD intersecting a first direction FD. The auxiliary electrode 65 may extend from the pixel area PIXA to the transmissive area TA in the first direction FD.

The cathode electrode 73 may directly receive a low power supply voltage transmitted from a power supply or power source (not shown) through a voltage supply pad (not shown) disposed at an edge of the display panel 110. For example, the cathode electrode 73 may receive the low power supply voltage transmitted from the power supply or power source at multiple locations through the auxiliary electrode 65.

In one or more aspects, a portion of the emission layer 72 disposed between the auxiliary electrode 65 and the cathode electrode 73 in the transmissive area TA may be melted and removed by laser irradiation, and a cathode contact 73A of the cathode electrode 73 may be electrically connected to the auxiliary electrode 65 through the portion of the emission layer 72 in which the emission layer 72 has been removed.

Although FIG. 5 shows only one cathode contact 73A, a plurality of cathode contacts 73A may be disposed in several portions of the display panel. Accordingly, a low power supply voltage can be supplied to the cathode electrode 73 through the plurality of cathode contacts 73A, and thereby, the organic light emitting display device 100 can provide an advantage of minimizing a difference in voltage between locations of the cathode electrode 73.

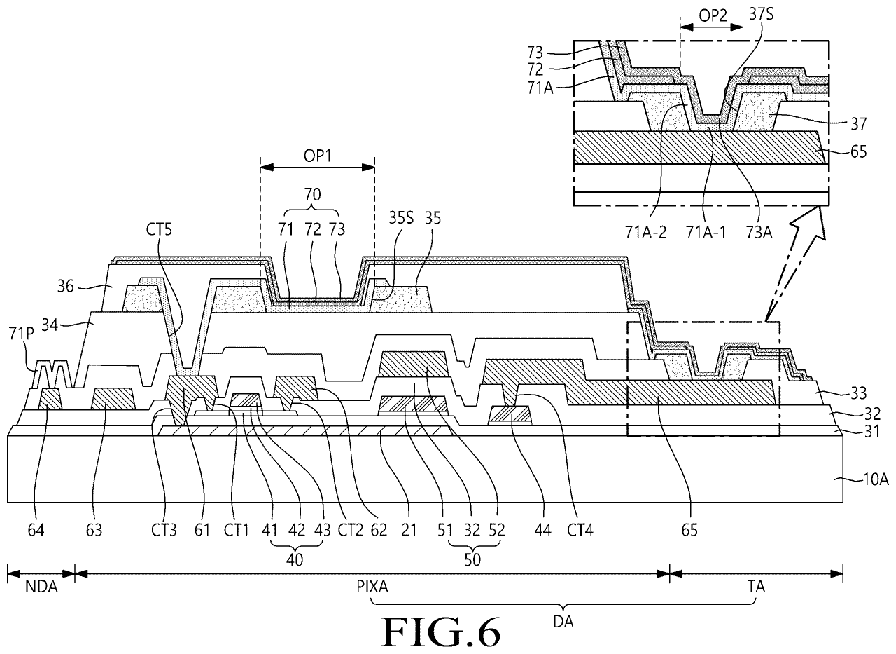

FIG. 6 is an example cross-sectional view of the organic light emitting display device in one or more example embodiments.

Referring to FIG. 6, a thin film transistor 40, a capacitor 50, a light emitting element 70, and an auxiliary electrode 65 may be disposed on a first substrate 10A.

The thin film transistor 40, capacitor 50, and light emitting element 70 may be disposed in the pixel area PIXA. The auxiliary electrode 65 may be disposed in the pixel area PIXA and extend from the pixel area PIXA to the transmissive area TA.

For example, a lower shield metal pattern 21 may be disposed on the first substrate 10A in the pixel area PIXA. The lower shield metal pattern 21 may be configured to overlap the thin film transistor 40 and the capacitor 50. The lower shield metal pattern 21 may serve to protect an active pattern 41 of the thin film transistor 40. The lower shield metal pattern 21 can prevent the generation of potential on a surface of the first substrate 10A and the entering of light from outside of the organic light emitting display device 100. The lower shield metal pattern 21 may include molybdenum (Mo), but example embodiments of the present disclosure are not limited thereto.

A buffer layer 31 may be disposed on the first substrate 10A and cover the lower shield metal pattern 21. The buffer layer 31 can protect the thin film transistor 40 from the penetration of moisture through the first substrate 10A, which is vulnerable to the penetration of moisture. The buffer layer 31 may include a plurality of inorganic layers, one or more of which are alternately stacked. For example, the buffer layer 31 may include a plurality of inorganic layers in which one or more of inorganic layers such as silicon oxide (SiOx), silicon nitride (SiNx), SiON, and the like are alternately stacked.

The thin film transistor 40 may be disposed on the buffer layer 31 in the pixel area PIXA. The thin film transistor 40 may include the active pattern 41, a gate insulating layer 42, and a gate electrode 43.

The active pattern 41 may include a channel region, and a source region and a drain region on both sides of the channel region. The thin film transistor 40 may be an oxide thin film transistor. In this implementation, the active pattern 41 may be include, for example, an oxide semiconductor. In another example, the active pattern 41 may include amorphous silicon (a-Si), polycrystalline silicon (poly-Si), an organic semiconductor, or the like. The gate insulating layer 42 and the gate electrode 43 may be configured to overlap with the channel region of the active pattern 41.

FIG. 6 illustrates the thin film transistor 40 having a top-gate structure in which the gate electrode 43 is located over the active pattern 41, but example embodiments of the present disclosure are not limited to this. For example, the thin film transistor 40 may have a bottom-gate structure in which the gate electrode 43 is located under the active pattern 41, or a double-gate structure in which gate electrodes 43 are located both over and under the active pattern 41.

The capacitor 50 may include a lower capacitor electrode 51, an interlayer insulating layer 32, and an upper capacitor electrode 52.

The lower capacitor electrode 51 may be disposed on the buffer layer 31 in the pixel area PIXA. A low power line 44 may be disposed on the buffer layer 31 in the pixel area PIXA and configured to be spaced apart from the lower capacitor electrode 51.

The gate electrode 43, the lower capacitor electrode 51, and the low power line 44 may include a same material. For example, the gate electrode 43, the lower capacitor electrode 51, and the low power line 44 may include a single layer or multiple layers containing one or more of molybdenum (Mo), aluminum (Al), chromium (Cr), gold (Au), titanium (Ti), nickel (Ni), neodymium (Nd), and copper (Cu), or one or more alloys of two or more of molybdenum (Mo), aluminum (Al), chromium (Cr), gold (Au), titanium (Ti), nickel (Ni), neodymium (Nd), and copper (Cu). An interlayer insulating layer 32 may be disposed on the buffer layer 31 and be configured to cover the gate electrode 43, the lower capacitor electrode 51, and the low power line 44.

A source electrode 61, a drain electrode 62, and the upper capacitor electrode 52 may be disposed on the interlayer insulating layer 32 in the pixel area PIXA. The source electrode 61 may be connected to the active pattern 41 through a first contact hole CT1 in the interlayer insulating layer 32, and the drain electrode 62 may be connected to the active pattern 41 through a second contact hole CT2 in the interlayer insulating layer 32. In one or more aspects, the source electrode 61 may be connected to the lower shield metal pattern 21 through a third contact hole CT3 in the interlayer insulating layer 32 and the buffer layer 31. The upper capacitor electrode 52 may be configured to overlap with the lower capacitor electrode 51.

For example, the thin film transistor 40 may be a scan thin film transistor (e.g., the scan transistor SCT of FIG. 3) or a driving thin film transistor (e.g., the driving transistor DRT of FIG. 3). The capacitor 50 may be a storage capacitor (e.g., the storage capacitor Cst of FIG. 3).

Lines (63 and 64) and the auxiliary electrode 65 may be disposed on the interlayer insulating layer 32. The lines (63 and 64) may be disposed in the display area DA and the non-display area NDA. The lines (63 and 64) may include, a gate line, a data line, and a power line, but example embodiments of the present disclosure are not limited to this.

The auxiliary electrode 65 may be connected to the low power line 44 through a fourth contact hole CT4 in the interlayer insulating layer 32 in the pixel area PIXA. The auxiliary electrode 65 may extend from the pixel area PIXA to the transmissive area TA. A portion of the auxiliary electrode 65 may be disposed in the pixel area PIXA, and another portion of the auxiliary electrode 65 may be disposed in the transmissive area TA.

The auxiliary electrode 65 may include the same material as at least one of the source electrode 61, the drain electrode 62, the upper capacitor electrode 52, and the lines (63 and 64). For example, the auxiliary electrode 65 may include a first metal layer containing an alloy of molybdenum and titanium (MoTi), a second metal layer disposed on the first metal layer and containing copper (Cu), and a third metal layer disposed on the second metal layer and containing an alloy (MoTi) of molybdenum and titanium.

A passivation layer 33 configured to cover the source electrode 61, the drain electrode 62, the upper capacitor electrode 52, the lines (63 and 64), and the auxiliary electrode 65 may be disposed on the interlayer insulating layer 32.

The passivation layer 33 may have an opening exposing a portion of a line 64 in the non-display area NDA. A pad 71P may be disposed on the portion of the line 64 exposed through the opening and a portion of the passivation layer 33 around the portion of the line 64 (e.g., a top portion, and/or one or more side portions, of the portion of the line 64). For example, the pad 71P may be one of a gate pad for transferring a gate voltage to be supplied to a subpixel, a data pad for transferring a data voltage to be supplied to the subpixel, and a voltage pad for transferring a low voltage or a high voltage to be supplied to the subpixel, but example embodiments of the present disclosure are not limited to this.

An overcoat layer 34 may be disposed on the passivation layer 33 in the pixel area PIXA. The overcoat layer 34 may include a photosensitive organic material. The overcoat layer 34 may include an organic insulating film such as polyacrylate, polyimide, and the like, but example embodiments of the present disclosure are not limited to this. The overcoat layer 34 may be formed through an exposure and development process.

A first insulating pattern 35 may be disposed on the overcoat layer 34. The first insulating pattern 35 may include a photosensitive organic material. The first insulating pattern 35 may include an organic insulating film such as polyacrylate, polyimide, and the like, but example embodiments of the present disclosure are not limited to this.

A first opening OP1 exposing a portion of the top surface of the overcoat layer 34 may be formed in the first insulating pattern 35 in the pixel area PIXA. A first inclined surface 35S of the first insulating pattern 35 may be exposed through the first opening OP1. The width of the first opening OP1 may be reduced toward one end closer to the first substrate 10A. The first inclined surface 35S of the first insulating pattern 35 may be tapered toward the first substrate 10A. The first inclined surface 35S of the first insulating pattern 35 may have an inclined angle less than 90 degrees with respect to the top surface of the first substrate 10A.

The first insulating pattern 35 may be formed through an exposure and development process. After the first insulating pattern 35 is formed through the exposure and development process, an amount of the inclined angle of the first inclined surface 35S of the first insulating pattern 35 may be adjusted through a pre-curing process. For example, an amount of the inclination angle of the first inclined surface 35S may be set as a target value for performing the pre-curing process.

Respective portions of the overcoat layer 34, the passivation layer 33, and the first insulating pattern 35 may be opened to form a fifth contact hole CT5 for exposing the source electrode 61.

An anode electrode 71 of the light emitting element 70 may be connected to the source electrode 61 through the fifth contact hole CT5. The anode electrode 71 may be disposed in one or more side portions (or side surfaces) of the first insulating pattern 35, one or more side portions (or side surfaces) of the overcoat layer 34, one or more side portions (or side surfaces) of the passivation layer 33, a top portion (or top surface) of the source electrode 61, which are exposed through the fifth contact hole CT5, and connected to the source electrode 61.

The anode electrode 71 may be disposed on the bottom surface of the first opening OP1 and the first inclined surface 35S of the first insulating pattern 35.

The passivation layer 33 may include an open area exposing a portion of the auxiliary electrode 65 in the transmission area TA. A second insulating pattern 37 may be disposed on the portion of the auxiliary electrode 65 exposed through the open area of the passivation layer 33. The second insulating pattern 37 may have a second opening OP2 exposing the portion of the auxiliary electrode 65. A second inclined surface 37S of the second insulating pattern 37 may be exposed through the second opening OP2. The width of the second opening OP2 may be reduced toward one end closer to the first substrate 10A. The second inclined surface 37S of the second insulating pattern 37 may be tapered toward the first substrate 10A. The second inclined surface 37S of the second insulating pattern 37 may have an inclined angle less than 90 degrees with respect to the top surface of the first substrate 10A.

In one or more aspects, the second insulating pattern 37 may include the same material as the first insulating pattern 35. An amount of the inclination angle of the second inclined surface 37S of the second insulating pattern 37 may be adjusted through the pre-curing process for adjusting the inclination angle of the first inclined surface 35S of the first insulating pattern 35. In one or more aspects, the second insulating pattern 37 may include the same material as the overcoat layer 34.

A connection electrode 71A may be disposed on an area including a portion of the top surface of the auxiliary electrode 65 exposed through the second opening OP2 and the second inclined surface 37S of the second insulating pattern 37. The connection electrode 71A may include a flat portion 71A-1 disposed on the portion of the upper surface of the auxiliary electrode 65 exposed through the second opening OP2 and an inclined portion (71A-2) disposed on the second inclined surface 37S of the second insulating pattern 37. The flat portion 71A-1 of the connection electrode 71A may directly contact the portion of the auxiliary electrode 65 exposed through the second opening OP2 and may be electrically connected to the auxiliary electrode 65.

The connection electrode 71A may be formed together with the anode electrode 71. The connection electrode 71A may include the same material as the anode electrode 71.

A bank 36 may be disposed on the overcoat layer 34, the first insulating pattern 35, and the anode electrode 71 in the pixel area PIXA. The bank 36 may expose a portion of the anode electrode 71 disposed on the bottom surface of the first opening OP1, and may cover another portion of the anode electrode 71 disposed on the first inclined surface 35S of the first insulating pattern 35.

An emission layer 72 may be disposed on the bank 36, a portion of the anode electrode 71 exposed by the bank 36, and the connection electrode 71A in the display area DA.

The emission layer 72 may be configured to correspond to all or some of a plurality of pixel areas PIXA and a plurality of transmissive areas TA included in the display area DA. The emission layer 72 may be formed using a mask having an open area corresponding to the display area DA.

The emission layer 72 may include a multi-layer structure in which two or more layers include organic materials having properties or compositions different from each other. For example, the emission layer 72 may include a light emitting layer including an organic light emitting material, and further include at least one of an electron injection layer, an electron transport layer, a hole transport layer, and a hole injection layer.

In one or more aspects, the emission layer 72 may be formed by a method of deposition or coating having straightness. For example, the emission layer 72 may be formed by a physical vapor deposition (PVD) method. The emission layer 72 formed by these methods may be configured such that a thickness of an area with a predefined angle to the substrate 10A is smaller than a thickness of an area parallel to the substrate 10A. Accordingly, a thickness of the emission layer 72 disposed on the second inclined surface 37S of the second insulating pattern 37 may be less than a thickness of the emission layer 71 disposed on the anode electrode 72 exposed through the bank 36.

A cathode electrode 73 may be disposed on the emission layer 72. The cathode electrode 73 may be formed on all or at least part of the emission layer 72. As a result, an organic light emitting element 70, for example, an organic light emitting diode, including the anode electrode 71 and the cathode electrode 73 facing each other, and the emission layer 72 interposed between them may be formed over the substrate 10A.

A portion of the emission layer 72 corresponding to the second opening OP2 may be removed as the portion of the emission layer 72 is irradiated by laser light from a laser. For example, a portion of the emission layer 72 disposed on the flat portion 71A-1 and the inclined portion 71A-2 of the connection electrode 71A may be melted and removed by laser irradiation. In this way, a cathode contact 73A may be formed. The cathode contact 73A may be a portion of the cathode electrode 73 in which the cathode contact 73A directly contacts the connection electrode 71A as the portion of the emission layer 72 is removed. Thus, the cathode contact 73A may allow the cathode electrode 73 to contact the flat portion 71A-1 and the inclined portion 71A-2 of the connection electrode 71A through the emission layer 72.

The second opening OP2 may be formed in the same process as the first opening OP1. In a plan view, a first electrode 71 (e.g., the anode electrode 71) or the connection electrode 71A may be disposed in an island shape on the first opening OP1 and the second opening OP2. The first electrode 71 or the connection electrode 71A may be disposed along respective shapes of the first opening OP1 and the second opening OP2, or respective shapes of the first insulating pattern 35 and the second insulating pattern 37. In the first opening OP1, the first electrode 71 may not cover a portion of the upper surface of the first insulating pattern 35 and another inclined surface facing the first inclined surface 35S of the first insulating pattern 35, and in the second opening OP2, the connection electrode 71A may cover all of the top surface of the second insulating pattern 37. In one or more aspects, a main light emitting area ER formed by the overlapping of the first electrode 71, the emission layer 72, and the second electrode 73, a non-light emitting area ANER surrounding the main light emitting area ER, and an additional light emitting area AER surrounding the non-light emitting area ANER and formed by light reflected from the first inclined surface 35S may be formed in the first opening OP1. In the second opening OP2, the emission layer 72 may be removed, and the connection electrode 71A and the second electrode 73 may contact each other along the inclined surface of the second insulating pattern 37 without the bank 36 being intervened therebetween.

As described above, since the emission layer 72 with a thin thickness is disposed on the second inclined surface 73A of the second insulating pattern 37, the emission layer 72 can be easily removed when removing the emission layer 72 by laser irradiation. Accordingly, the cathode contact can be successfully formed.

As the connection electrode 71A includes the flat portion 71A-1 disposed on the top surface of the auxiliary electrode 65 and the inclined portion 71A-2 disposed on the second inclined surface 37S of the second insulating pattern 37, and the cathode contact 73A contacts the flat portion 71A-1 and the inclined portion 71A-2 of the connection electrode 71A, a contact area between the cathode contact 73A and the connection electrode 71A may be increased without increasing an area occupied by the cathode contact 73A, and thereby, the cathode contact can be more successfully formed.

Since the cathode contact can be more successfully formed, the area occupied by the cathode contact 73A and the number of cathode contacts 73A can be reduced, and in turn, the transparency of one or more transmissive area TA can be improved.

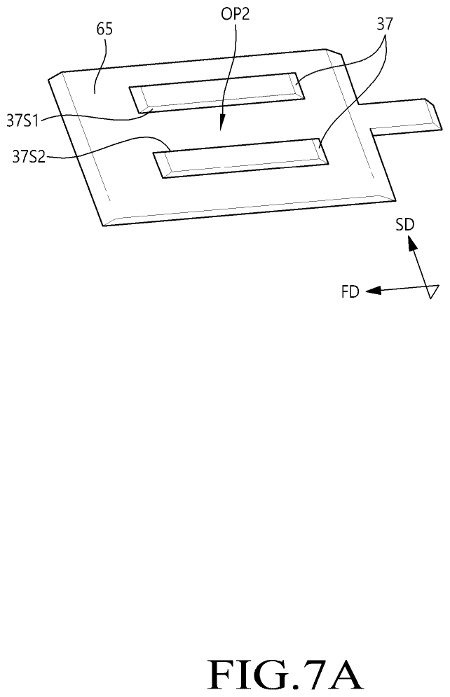

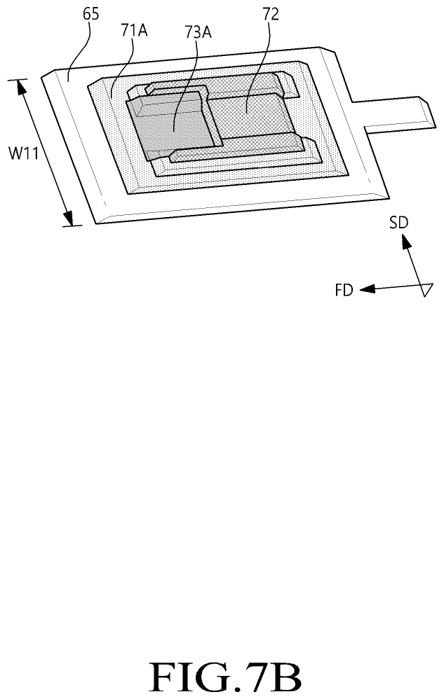

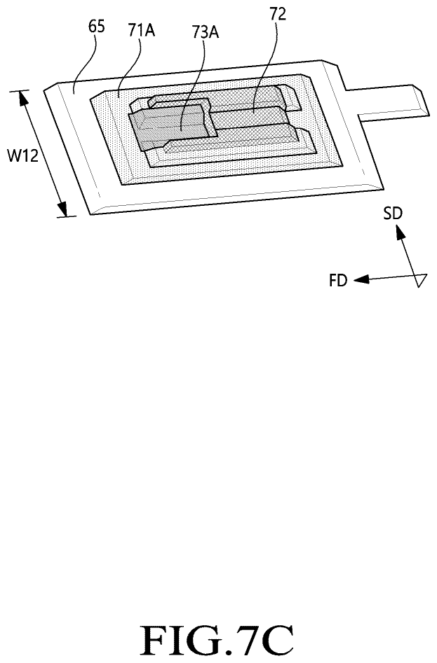

FIGS. 7A to 7C, 8A to 8B, and 9A to 9B are perspective views illustrating the process of forming a cathode contact in the organic light emitting display device 100 in one or more example embodiments.

Referring to FIG. 7A, an auxiliary electrode 65 may protrude from a pixel area to a transmissive area in a first direction FD.

A second insulating pattern 37 including a second opening OP2 exposing a portion of the auxiliary electrode 65 may be disposed on the auxiliary electrode 65. The second opening OP2 of the second insulating pattern 37 may have a line shape extending in the first direction FD. The second insulating pattern 37 may be exposed through the second opening OP2, and include a pair of inclined surfaces (37S1 and 37S2) facing each other in a second direction SD.

Referring to FIG. 7B, a connection electrode 71A may be disposed on the auxiliary electrode 65 and the second insulating pattern (37 in FIG. 7A). The connection electrode 71A may cover the inclined surfaces (37S1 and 37S2 in FIG. 7A) of the second insulating pattern (37 in FIG. 7A) exposed through the second opening (OP2 in FIG. 7A), and the top surface of the auxiliary electrode 65 between the inclined surfaces (37S1 and 37S2). The connection electrode 71A may be disposed in the form of thin film on the inclined surfaces (37S1 and 37S2 in FIG. 7A) of the second insulating pattern (37 in FIG. 7A) and the top surface of the auxiliary electrode 65 between the inclined surfaces (37S1 and 37S2). The connection electrode 71A may have surface irregularities corresponding to the shape of the inclined surfaces (37S1 and 37S2 in FIG. 7A) of the second insulating pattern (37 in FIG. 7A) and the top surface of the auxiliary electrode 65 between the inclined surfaces (37S1 and 37S2).

After an emission layer 72 and a cathode electrode 73 are sequentially stacked on the connection electrode 71A, an area corresponding to a portion of the second opening (OP2 in FIG. 7A) may be irradiated by laser light from a laser, and thereby, the emission layer 72 can be removed. In this manner, the emission layer 72 disposed on the inclined surfaces (37S1 and 37S2 in FIG. 7A) of the second insulating pattern (37 in FIG. 7A) exposed through the second opening (OP2 in FIG. 7A) and the top surface of the auxiliary electrode 65 between the inclined surfaces (37S1 and 37S2 in FIG. 7A) may be melted and removed by the laser irradiation.

As the emission layer 72 is removed, a portion of the cathode electrode 73 may contact the connection electrode 71A on the inclined surfaces (37S1 and 37S2 in FIG. 7A) of the second insulating pattern (37 in FIG. 7A) and the auxiliary electrode 65 between the inclined surfaces (37S1 and 37S2), and thereby, the cathode contact 73A may be formed.

The cathode contact 73A may contact the connection electrode 71A on the inclined surfaces (37S1 and 37S2 in FIG. 7A) of the second insulating pattern (37 in FIG. 7A) and the auxiliary electrode 65 between the inclined surfaces (37S1 and 37S2). The cathode contact 73A may contact the surface irregularities of the connection electrode 71A corresponding to the shape of the inclined surfaces (37S1 and 37S2 in FIG. 7A) of the second insulating pattern (37 in FIG. 7A) and the top surface of the auxiliary electrode 65 between the inclined surfaces (37S1 and 37S2). Accordingly, a contact area between the cathode contact 73A and the connection electrode 71A may become larger than an area occupied by the cathode contact 73A, and thereby, the cathode contact can be successfully formed.

Since the cathode contact can be successfully formed, as shown in FIG. 7C, a width of the cathode contact 73A may be reduced from W11 to W12, and an area occupied by the cathode contact 73A may be reduced. Thereby, the transparency of the transmissive area can be improved.

FIGS. 7A to 7C illustrate the example where the cathode contact 73A is disposed on the inclined surfaces (37S1 and 37S2 in FIG. 7A) facing each other in the second direction SD and the auxiliary electrode 65 between the inclined surfaces (37S1 and 37S2), but example embodiments of the present disclosure are not limited to this.

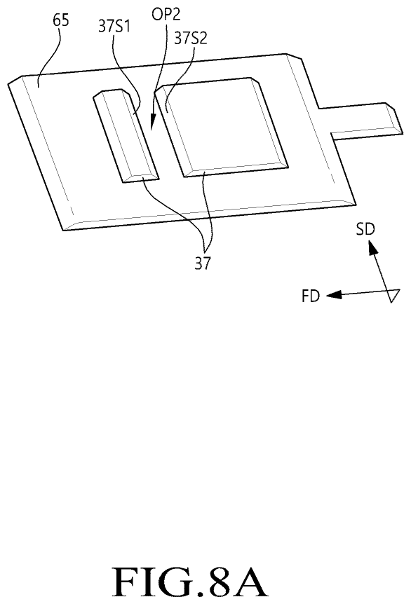

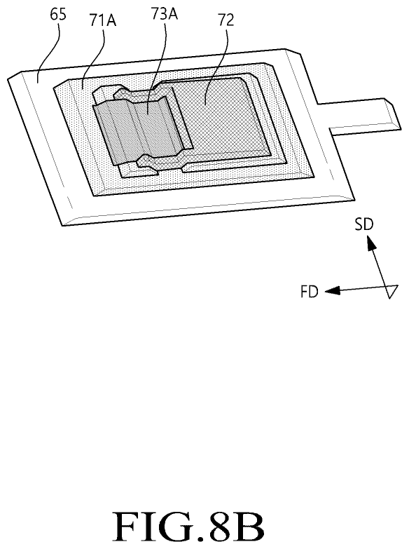

In one or more aspects, as shown in FIG. 8A, a second insulating pattern 37 may have a pair of inclined surfaces (37S1 and 37S2) facing each other in the first direction FD, and as shown in FIG. 8B, a cathode contact 73A may be disposed on the inclined surfaces (37S1 and 37S2 in FIG. 8A) facing each other in the first direction FD and an auxiliary electrode 65 between the inclined surfaces (37S1 and 37S2 in FIG. 8A).

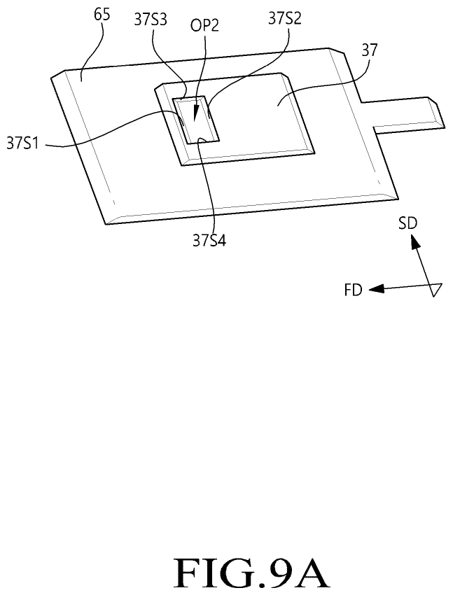

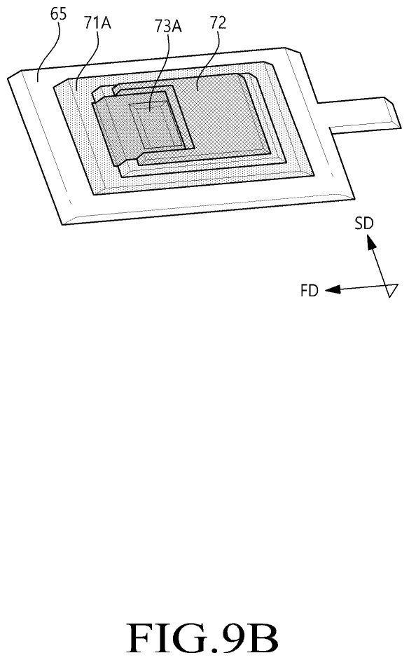

In one or more aspects, as shown in FIG. 9A, a second insulating pattern 37 may have a pair of inclined surfaces (37S1 and 37S2) facing each other in the first direction FD and another pair of inclined surfaces (37S3 and 37S4) facing each other in the second direction SD, and as shown in FIG. 9B, a cathode contact 73A may be disposed on the two pairs of inclined surfaces (37S1, 37S2, 37S3, and 37S4 in FIG. 9A) and an auxiliary electrode 65 surrounded by the two pairs of inclined surfaces (37S1, 37S2, 37S3, and 37S4 in FIG. 9A).

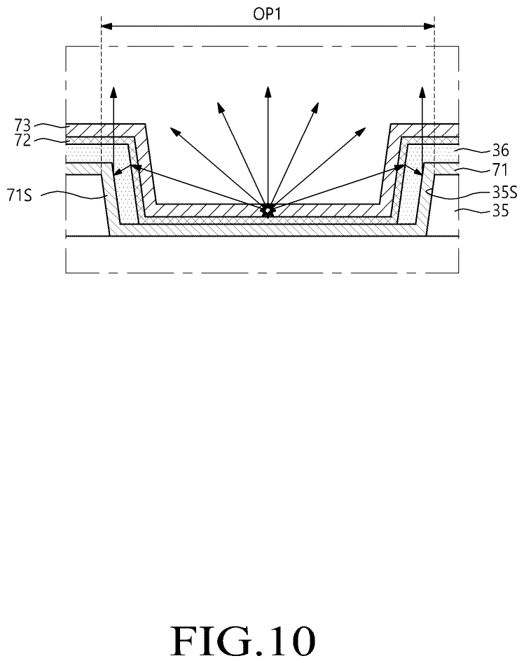

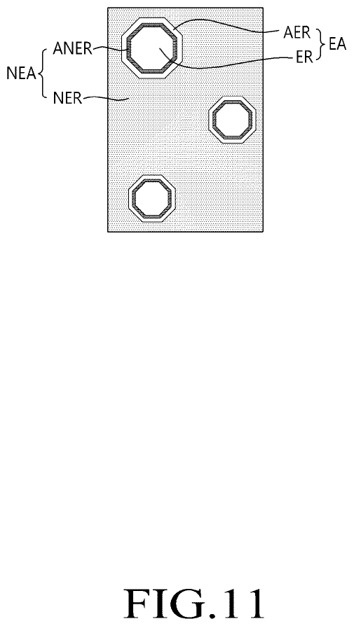

FIG. 10 illustrates that light emitted from an emission layer in the display device according to aspects of the present disclosure is reflected by an anode electrode. FIG. 11 illustrates that light emitting areas and non-light emitting areas in the display device according to aspects of the present disclosure.

Referring to FIG. 10, light emitted from an emission layer 72 may not be oriented in a specific direction, and may be radiated in various directions.

Light reaching an inclined portion 71S (e.g., the inclined portion 71S in the figures discussed above) of an anode electrode 71 (e.g., the anode electrode 71 in the figures discussed above) may be reflected by the inclined portion 71S of the anode electrode 71 and be cause to move outside of the display device. Accordingly, the display device can provide advantages of having improved light extraction efficiency, and presenting high luminance. Further, the display device can have advantages of providing a sufficient amount of light with low power as light extraction efficiency is improved, and thereby, reducing power consumption. Further, the display device can have an additional advantage of providing a wide viewing angle.

Referring to FIG. 11, a plurality of light emitting areas EA corresponding to a plurality of subpixels may be formed in a pixel area PIXA. The remainder of the pixel area PIXA except for the plurality of light emitting areas EA may correspond to a non-light emitting area NEA. Respective areas of light emitting areas EA of at least two subpixels may be different from each other, but example embodiments of the present disclosure are not limited to this.

Each of at least one light emitting area EA formed in the pixel area PIXA may include a plurality of light emitting areas (ER and AER). For example, one light emitting area EA may include a main light emitting area ER and an additional light emitting area AER surrounding the main light emitting area ER.

The non-light emitting area NEA may include a non-light emitting area NER and an additional non-light emitting area ANER. The additional non-light emitting area ANER may be disposed between the main light emitting area ER and the additional light emitting area AER. For example, the main light emitting area ER and the additional light emitting area AER may be divided by the additional non-light emitting area ANER. An area of the additional non-light emitting area ANER may be less than that of the main light emitting area ER.

When the display device is in a turn-on state, the additional non-light emitting area ANER may be in a black state or in a state of presenting luminance lower than the main light emitting area ER and the additional light emitting area AER due to light incident from at least one of the main light emitting area ER and the additional light emitting area AER. The non-light emitting area NER may be disposed between a plurality of light emitting areas EA. For example, adjacent light emitting areas EA may be distinct from each other by a non-light emitting area NER.

The main light emitting area ER may have an oval shape in a plan view. The additional non-light emitting area ANER and the additional light emitting area AER may have an oval ring shape along the main light emitting area ER with the oval shape. However, example embodiments of the present disclosure are not limited to this. For example, the main light emitting area ER may have a circular, oval, or polygonal shape in a plan view. The polygonal shape may be, for example, a triangle, a square, or an octagon, or one or more combinations thereof. The shapes of the additional non-light emitting area ANER and the additional light emitting area AER may vary depending on the shape of the main light emitting area ER.

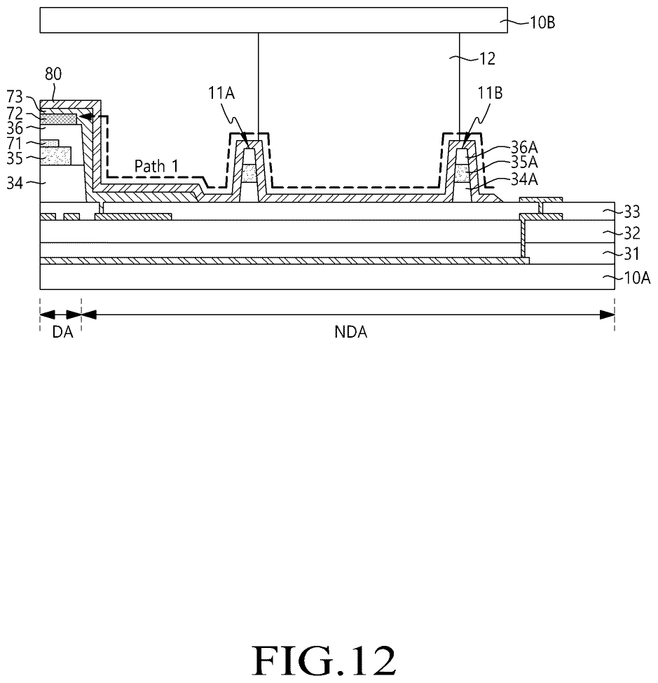

FIGS. 12 to 14 are example cross-sectional views illustrating an inner dam, an outer dam, and a sealing dam in the display device 100 in one or more example embodiments.

Referring to FIG. 12, an inner dam 11A and an outer dam 11B may be disposed over a first substrate 10A in a non-display area NDA.

The inner dam 11A may be configured to surround a display area DA. The outer dam 11B may be located outside of the inner dam 11A and configured to surround the inner dam 11A.

Each of the inner dam 11A and the outer dam 11B may include a plurality of layers (34A, 35A, and 36A). For example, each of the inner dam 11A and the outer dam 11B may include a first layer 34A, a second layer 35A on the first layer 34A, and a third layer 36A on the second layer 35A.

The first layer 34A may be formed through the same process as an overcoat layer 34. When the overcoat layer 34 is formed in the display area DA, the first layer 34A with a predetermined thickness may be prepared through the same process as the overcoat layer 34, and thereafter, the first layer 34A may be disconnected from the overcoat layer 34 through a patterning process.

The second layer 35A may be formed through the same process as a first insulating pattern 35. When the first insulating pattern 35 is formed in the display area DA, the second layer 35A with a predetermined thickness may be prepared through the same process as the first insulating pattern 35, and thereafter, the second layer 35A may be disconnected from the first insulating pattern 35 through a patterning process.

The third layer 36A may be formed through the same process as a bank 36. When the bank 36 is formed in the display area DA, the third layer 36A with a predetermined thickness may be prepared through the same process as the bank 36, and thereafter, the third layer 36A may be disconnected from the bank 36 through a patterning process.

A sealing layer 80 covering a cathode electrode 73, the inner dam 11A, and the outer dam 11B may be disposed on the display area DA and the non-display area NDA. The sealing layer 80 can protect light emitting elements such as organic light emitting diodes and the like disposed in the display area DA from the outside of the display device. The sealing layer 80 can shield the light emitting elements from the penetration of moisture, and thereby, reduce or delay the degradation of the light emitting elements due to moisture.

A sealing dam 12 may be disposed between the inner dam 11A and the outer dam 11B, and bond a first substrate 10A and a second substrate 10B. The sealing dam 12 can improve the reliability of preventing the penetration of moisture by reducing or suppressing the penetration of moisture from the outside of the display device into light emitting elements ED such as electroluminescent elements, organic light emitting diodes, and the like.

According to the example of FIG. 12, respective heights of the inner dam 11A and the outer dam 11B can be increased by forming the second layers 35A of the inner dam 11A and the outer dam 11B in the process of forming the first insulating pattern 35. Accordingly, the increased heights of the inner dam 11A and the outer dam 11B can cause the length of a moisture penetration path Path 1 to increase, and thereby, the reliability of preventing the penetration of moisture can be improved.

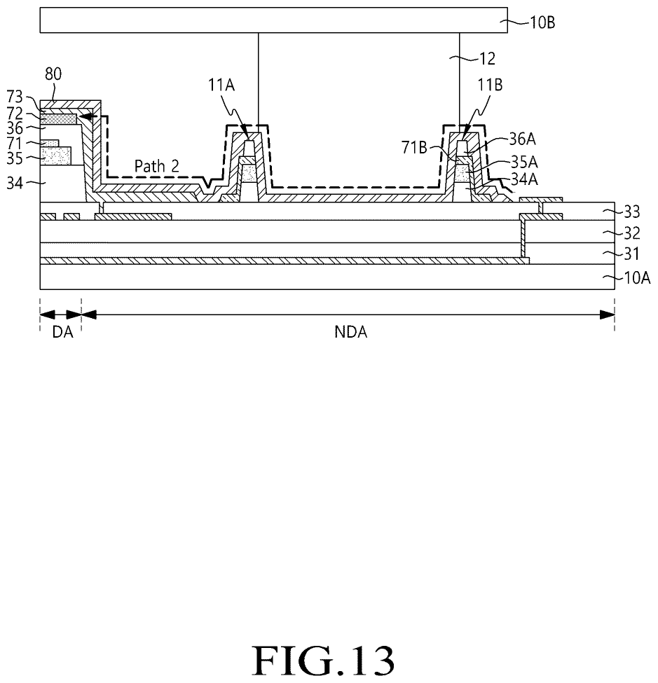

Referring to FIG. 13, each of an inner dam 11A and an outer dam 11B may include a plurality of layers (34A, 35A, 71B, and 36A). For example, each of an inner dam 11A and an outer dam 11B may include a first layer 34A, a second layer 35A on the first layer 34A, a third layer 36A on the second layer 35A, and an electrode pattern 71B between the second layer 35A and the third layer 36A. The inner dam 11A and the outer dam 11B of FIG. 13 may further include the electrode pattern 71B compared to the configuration of FIG. 12.

The electrode pattern 71B may be formed through the same process as an anode electrode 71. The electrode pattern 71B may be formed together with the anode electrode 71 when the anode electrode 71 is formed in the display area DA.

The inner dam 11A may have an outer surface facing the outer dam 11B and an inner surface opposite to the outer surface. The outer dam 11B may have an inner surface facing the inner dam 11A and an outer surface opposite to the inner surface.

The electrode pattern 71B of the inner dam 11A may extend to the inner surface of the inner dam 11A and cover the second layer 35A and the first layer 34A on the inner surface of the inner dam 11A. The electrode pattern 71B of the inner dam 11A may not extend to the outer surface of the inner dam 11A. The electrode pattern 71B may be configured not to cover the second layer 35A and the first layer 34A on the outer surface of the inner dam 11A.

The electrode pattern 71B of the outer dam 11B may extend to the outer surface of the outer dam 11B and cover the second layer 35A and the first layer 34A on the outer surface of the outer dam 11B. The electrode pattern 71B of the outer dam 11B may not extend to the inner surface of the outer dam 11B. The electrode pattern 71B may be configured not to cover the second layer 35A and the first layer 34A on the inner surface of the outer dam 11B.

According to the example of FIG. 13, respective heights of the inner dam 11A and the outer dam 11B can be increased by forming the electrode pattern 71B in the process of forming the anode electrode 71. Accordingly, the increased heights of the inner dam 11A and the outer dam 11B can cause the length of a moisture penetration path Path 2 to increase, and thereby, the reliability of preventing the penetration of moisture can be more improved.

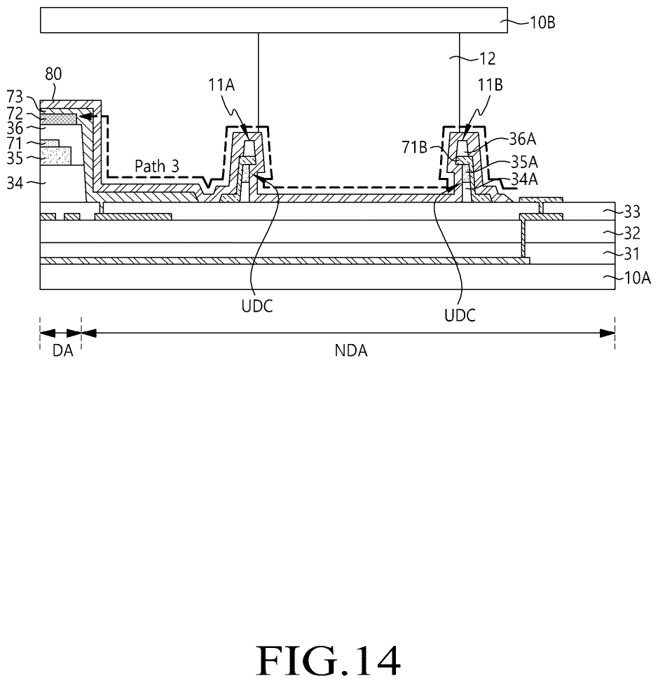

Referring to FIG. 14, each of an inner dam 11A and an outer dam 11B may include a first layer 34A, a second layer 35A, an electrode pattern 71B, a third layer 36A, and an undercut structure UDC. The inner dam 11A and the outer dam 11B of FIG. 14 may further include the undercut structure UDC compared to the configuration of FIG. 13.

The inner dam 11A may have a structure in which the first layer 34A and the second layer 35A are not covered by the electrode pattern 71B on an outer surface facing the outer dam 11B. The first layer 34A and the second layer 35A may be recessed on the outer surface of the inner dam 11A, which is not covered by the electrode pattern 71B, to provide an undercut structure UDC. The inner dam 11A may have the undercut structure UDC on the outer surface in which the first layer 34A and the second layer 35A are recessed inwards (e.g., leftwards) with respect to the third layer 36A.

The outer dam 11B may have a structure in which the first layer 34A and the second layer 35A are not covered by the electrode pattern 71B on an inner side facing the inner dam 11A. The first layer 34A and the second layer 35A may be recessed on the inner surface of the outer dam 11B, which is not covered by the electrode pattern 71B, to provide an undercut structure UDC. The outer dam 11B may have the undercut structure UDC on the inner surface in which the first layer 34A and the second layer 35A are recessed outwards (e.g., rightwards) with respect to the third layer 36A.

According to the example of FIG. 14, the length of a moisture penetration path Path 3 can be increased by forming the undercut structures UDC in each of the inner dam 11A and the outer dam 11B, and thereby, the reliability of preventing the penetration of moisture can be more improved.

The example embodiments described above for the organic light emitting display device 100 will be briefly described as follows.

According the example embodiments described herein, an organic light emitting display device can be provided that includes: a substrate in which a pixel area and a transmissive area are defined; an overcoat layer disposed over the substrate in the pixel area; a first insulating pattern disposed on the overcoat layer, and including a first opening exposing a portion of the overcoat layer and a first inclined surface exposed by the first opening; an anode electrode disposed on the portion of the overcoat layer exposed through the first opening and the first inclined surface of the first insulating pattern; an auxiliary electrode disposed over the substrate in the transmissive area; a second insulating pattern disposed on the auxiliary electrode, and including a second opening exposing a portion of the auxiliary electrode and a second inclined surface exposed by the second opening; a connection electrode including a flat portion disposed on the portion of the auxiliary electrode exposed through the second opening and an inclined portion disposed on the second inclined surface of the second insulating pattern; an emission layer disposed in the pixel area and the transmissive area and covering the anode electrode and the connection electrode; and a cathode electrode disposed on the emission layer, and including a cathode contact passing through the emission layer and contacting the flat portion and the inclined portion of the connection electrode.

In one or more aspects, the second inclined surface may be tapered toward the substrate.

In one or more aspects, the second insulating pattern may include a same material as the first insulating pattern.

In one or more aspects, the second insulating pattern may include a same material as the overcoat layer.

In one or more aspects, the connection electrode may include a same material as the anode electrode.

In one or more aspects, the display device may further include a thin film transistor disposed over the substrate in the pixel area; an interlayer insulating layer covering the thin film transistor; a source electrode and a drain electrode disposed on the interlayer insulating layer and connected to the thin film transistor through contact holes in the interlayer insulating layer; and a passivation layer disposed on the interlayer insulating layer and covering the source electrode and the drain electrode. The overcoat layer may be disposed on the passivation layer.

In one or more aspects, the auxiliary electrode may be disposed on the interlayer insulating layer.

In one or more aspects, the auxiliary electrode may include a same material as the source electrode and the drain electrode.

In one or more aspects, the passivation layer may include an open area exposing a portion of the auxiliary electrode in the transmissive area, and the second insulating pattern may be disposed in the open area.

According the example embodiments described herein, an organic light emitting display device can be provided that includes: a first substrate in which a display area and a non-display area surrounding the display area are defined; a second substrate facing the first substrate and overlapping with the first substrate; at least one thin film transistor disposed over the first substrate in the display area; an interlayer insulating layer disposed over the first substrate and covering the at least one thin film transistor; a passivation layer disposed on the interlayer insulating layer; an overcoat layer disposed on the passivation layer in the display area; a first insulating pattern disposed on the overcoat layer, and including a first opening exposing a portion of the overcoat layer and a first inclined surface exposed by the first opening; an anode electrode disposed on the portion of the overcoat layer exposed through the first opening and the first inclined surface of the first insulating pattern; a bank disposed on the first insulating pattern and the anode electrode, and exposing a portion of the anode electrode disposed on the bottom of the first opening; and at least one dam disposed on the passivation layer in the non-display area, and surrounding the display area. The at least one dam may include a plurality of layers, and one of the plurality of layers may include the same material as the first insulating pattern.

In one or more aspects, each of the at least one dam may include a first layer including a same material as the overcoat layer, a second layer disposed on the first layer and including a same material as the first insulating pattern, and a third layer disposed on the second layer and including a same material as the bank.

In one or more aspects, each of the at least one dam may further include an electrode pattern disposed between the second layer and the third layer.

In one or more aspects, the electrode pattern may include a same material as the anode electrode.

In one or more aspects, the at least one dam may include an inner dam surrounding the display area, and an outer dam located outside of the inner dam and surrounding the inner dam.

In one or more aspects, the display device may further include a sealing dam disposed between the inner dam and the outer dam and contacting at least one of the first substrate and the second substrate.

In one or more aspects, the inner dam may include an outer surface facing the outer dam and an inner surface opposite to the outer surface, and the inner dam may have a structure in which the electrode pattern covers the first layer and the second layer on the inner side surface, and does not cover the first layer and the second layer on the outer side surface.

In one or more aspects, the inner dam may further include an undercut structure on the outer surface in which the first and second layers are recessed inwards or leftwards with respect to the third layer.

In one or more aspects, the outer dam may include an inner surface facing the inner dam and an outer surface opposite to the inner surface, and the outer dam may have a structure in which the electrode pattern covers the first layer and the second layer on the outer side surface, and does not cover the first layer and the second layer on the inner side surface.

n one or more aspects, the outer dam may further include an undercut structure on the inner surface in which the first and second layers are recessed outwards or rightwards with respect to the third layer.

According to the example embodiments described herein, an organic light emitting display device can be provided that includes: a substrate in which a pixel area and a transmissive area are defined; an anode electrode disposed over the substrate in the pixel area; an auxiliary electrode disposed over the substrate in the transmissive area; an insulating pattern disposed on the auxiliary electrode, and including an opening exposing a portion of the auxiliary electrode and an inclined surface exposed by the opening; a connection electrode including a flat portion disposed on the portion of the auxiliary electrode exposed through the opening and an inclined portion disposed on the inclined surface of the insulating pattern; an emission layer disposed in the pixel area and the transmissive area, and covering the anode electrode and the connection electrode; and a cathode electrode disposed on the emission layer, and including a cathode contact passing through the emission layer and contacting the flat portion and the inclined portion of the connection electrode.

According to one or more aspects described herein, an organic light emitting display device may be provided that is capable of improving transparency of a transmissive area by reducing the number of cathode contacts and reducing an area occupied by each cathode contact.

According to one or more aspects described herein, an organic light emitting display device may be provided that is capable of increasing the probability of successfully forming cathode contacts without reducing the transparency of a transmissive area by increasing an area contacted by each cathode contact without reducing an area occupied by each cathode contact.

According to one or more aspects described herein, an organic light emitting display device may be provided that is capable of increasing the probability of successfully forming cathode contacts by reducing the thickness of an emission layer disposed in an area where each cathode contact is formed, and thereby, causing the emission layer to be easily removed in the process of removing the emission layer using a laser.

According to one or more aspects described herein, an organic light emitting display device may be provided that is capable of being driven with low power by lowering the resistance of a cathode electrode and reducing voltage drop.

According to one or more aspects described herein, an organic light emitting display device may be provided that is capable of lengthening a path through which moisture penetrates, and improving the reliability of the display device by preventing or reducing the penetration of moisture coming from outside of the organic light emitting display device.

According to one or more aspects described herein, an organic light emitting display device may be provided that is capable of lengthening a path through which moisture penetrates, and enabling a narrow bezel to be achieved by preventing or reducing the penetration of moisture without increasing the width of the bezel.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light emitting display device comprising:
a substrate having a pixel area and a transmissive area;
an overcoat layer on the substrate in the pixel area;
a first insulating pattern on the overcoat layer, the first insulating pattern including a first opening exposing a portion of the overcoat layer and a first inclined surface exposed by the first opening;
an anode electrode on the portion of the overcoat layer exposed through the first opening and the first inclined surface of the first insulating pattern;
an auxiliary electrode on the substrate in the transmissive area;
a second insulating pattern on the auxiliary electrode, the second insulating pattern including a second opening exposing a portion of the auxiliary electrode and a second inclined surface exposed by the second opening;
a connection electrode including a flat portion on the portion of the auxiliary electrode exposed through the second opening and an inclined portion on the second inclined surface of the second insulating pattern;
an emission layer disposed in the pixel area and the transmissive area and covering the anode electrode and the connection electrode; and
a cathode electrode on the emission layer, the cathode electrode including a cathode contact passing through the emission layer and contacting the flat portion and the inclined portion of the connection electrode.

2. The organic light emitting display device of claim 1, wherein the second inclined surface is tapered toward the substrate.

3. The organic light emitting display device of claim 1, wherein the second insulating pattern comprises a same material as the first insulating pattern.

4. The organic light emitting display device of claim 1, wherein the second insulating pattern comprises a same material as the overcoat layer.

5. The organic light emitting display device of claim 1, wherein the connection electrode comprises a same material as the anode electrode.

6. The organic light emitting display device of claim 1, further comprising:
a thin film transistor on the substrate in the pixel area;
an interlayer insulating layer covering the thin film transistor;
a source electrode and a drain electrode on the interlayer insulating layer and connected to the thin film transistor through contact holes in the interlayer insulating layer; and
a passivation layer on the interlayer insulating layer and covering the source electrode and the drain electrode,
wherein the overcoat layer is on the passivation layer.

7. The organic light emitting display device of claim 6, wherein the auxiliary electrode is on the interlayer insulating layer.

8. The organic light emitting display device of claim 6, wherein the auxiliary electrode comprises a same material as the source electrode and the drain electrode.

9. The organic light emitting display device of claim 6, wherein the passivation layer comprises an open area exposing a portion of the auxiliary electrode in the transmissive area, and the second insulating pattern is disposed in the open area.

10. An organic light emitting display device comprising:
a first substrate having a display area and a non-display area adjacent to the display area;
a second substrate facing the first substrate and overlapping with the first substrate;
at least one thin film transistor on the first substrate in the display area;
an interlayer insulating layer on the first substrate and covering the at least one thin film transistor;
a passivation layer on the interlayer insulating layer;
an overcoat layer on the passivation layer in the display area;
a first insulating pattern on the overcoat layer, the first insulating pattern including a first opening exposing a portion of the overcoat layer and a first inclined surface exposed by the first opening;
an anode electrode on the portion of the overcoat layer exposed through the first opening and the first inclined surface of the first insulating pattern;
a bank on the first insulating pattern and the anode electrode, and exposing a portion of the anode electrode disposed on a bottom of the first opening; and
at least one dam on the passivation layer in the non-display area, and surrounding the display area from a plan view,
wherein the at least one dam includes a plurality of layers, and one of the plurality of layers comprises a same material as the first insulating pattern.

11. The organic light emitting display device of claim 10, wherein each of the at least one dam comprises:
a first layer including a same material as the overcoat layer;
a second layer on the first layer and including a same material as the first insulating pattern; and
a third layer on the second layer and including a same material as the bank.

12. The organic light emitting display device of claim 11, wherein each of the at least one dam further comprises an electrode pattern disposed between the second layer and the third layer.

13. The organic light emitting display device of claim 12, wherein the electrode pattern comprises a same material as the anode electrode.

14. The organic light emitting display device of claim 12, wherein the at least one dam comprises:
an inner dam surrounding the display area from a plan view; and
an outer dam located outside of the inner dam and surrounding the inner dam from a plan view.

15. The organic light emitting display device of claim 14, further comprising a sealing dam disposed between the inner dam and the outer dam and contacting at least one of the first substrate and the second substrate.

16. The organic light emitting display device of claim 14, wherein the inner dam comprises an outer surface facing the outer dam and an inner surface opposite to the outer surface, and
wherein the inner dam has a structure in which the electrode pattern covers the first layer and the second layer on the inner side surface, and does not cover the first layer and the second layer on the outer side surface.

17. The organic light emitting display device of claim 16, wherein the inner dam further comprises an undercut structure on the outer surface in which the first and second layers are recessed inwards or leftwards with respect to the third layer.

18. The organic light emitting display device of claim 14, wherein the outer dam comprises an inner surface facing the inner dam and an outer surface opposite to the inner surface, and
wherein the outer dam has a structure in which the electrode pattern covers the first layer and the second layer on the outer side surface, and does not cover the first layer and the second layer on the inner side surface.

19. The organic light emitting display device of claim 18, wherein the outer dam further comprises an undercut structure on the inner surface in which the first and second layers are recessed outwards or rightwards with respect to the third layer.

20. An organic light emitting display device comprising:
a substrate in which a pixel area and a transmissive area are defined;
an anode electrode disposed over the substrate in the pixel area;
an auxiliary electrode disposed over the substrate in the transmissive area;
an insulating pattern disposed on the auxiliary electrode, and comprising an opening exposing a portion of the auxiliary electrode and an inclined surface exposed by the opening;
a connection electrode including a flat portion disposed on the portion of the auxiliary electrode exposed through the opening and an inclined portion disposed on the inclined surface of the insulating pattern;
an emission layer disposed in the pixel area and the transmissive area and covering the anode electrode and the connection electrode; and
a cathode electrode disposed on the emission layer, and comprising a cathode contact passing through the emission layer and contacting the flat portion and the inclined portion of the connection electrode.
